(19) United States
(12) Patent Application Publication
(10) Pub. No.: US 2026/0068265 A1
(43) Pub. Date: Mar. 5, 2026

(54) SEMICONDUCTOR DEVICE

(71) Applicant: SUMITOMO ELECTRIC DEVICE INNOVATIONS, INC., Kanagawa (JP)

(72) Inventor: Kenichi WATANABE, Kanagawa (JP)

(21) Appl. No.: 19/305,020

(22) Filed: Aug. 20, 2025

(30) Foreign Application Priority Data
Aug. 29, 2024 (JP) 2024-147662

(51) Int. Cl. H10D 64/00; H10D 30/47

(52) U.S. Cl. CPC H10D 64/118; H10D 30/472

(57) ABSTRACT

A semiconductor device includes a first inorganic insulating film covering a first metal layer over a substrate and having a first opening exposing a central area of an upper surface of the first metal layer, a second metal layer on the first metal layer and having a lower surface, a central area of the lower surface contacting the first metal layer through the first opening, a peripheral area of the lower surface contacting the first inorganic insulating film around the first opening, a second inorganic insulating film covering the second metal layer and having a second opening exposing a central area of an upper surface of the second metal layer, and an organic insulating film covering the second inorganic insulating film and having an opening exposing a central area of the upper surface of the second metal layer and overlapping with the second opening when viewed from a thickness direction.

### CROSS-REFERENCE TO RELATED APPLICATION

This application is based on and claims priority to Japanese Patent Application No. 2024-147662 filed on Aug. 29, 2024, the entire contents of which are incorporated herein by reference.

### TECHNICAL FIELD

The present disclosure relates to semiconductor devices.

### BACKGROUND

As known in the art, an insulating film having an opening exposing a central area of the upper surface of the metal layer may be disposed to cover the metal layer used as a pad or the like (see Japanese Laid-Open Patent Publication No. 2018-56246, for example). As the insulating film, a silicon nitride film is used.

### SUMMARY

According to at least one embodiment, a semiconductor device includes a substrate; a first metal layer disposed over the substrate, a first inorganic insulating film covering the first metal layer and having a first opening exposing a central area of an upper surface of the first metal layer, a second metal layer disposed on the first metal layer and having a lower surface, a central area of the lower surface being in contact with the first metal layer through the first opening, a peripheral area of the lower surface being in contact with the first inorganic insulating film around the first opening, a second inorganic insulating film covering the second metal layer and having a second opening exposing a central area of an upper surface of the second metal layer, and an organic insulating film covering the second inorganic insulating film and having a third opening exposing a central area of the upper surface of the second metal layer and overlapping with the second opening when viewed from a thickness direction of the substrate.

### BRIEF DESCRIPTION OF THE DRAWINGS

FIG. 1 is a cross-sectional view of a semiconductor device according to a first embodiment;

FIG. 2 is a plan view illustrating metal layers and openings in the semiconductor device according to the first embodiment;

FIG. 3 is a cross-sectional view of a semiconductor device according to a comparative example;

FIG. 4 is a cross-sectional view of the semiconductor device according to the first embodiment;

FIG. 5 is an enlarged cross-sectional view of the semiconductor device according to the first embodiment;

FIG. 6 is a cross-sectional view illustrating a method of manufacturing the semiconductor device according to the first embodiment;

FIG. 7 is a cross-sectional view illustrating the method of manufacturing the semiconductor device according to the first embodiment;

FIG. 8 is a cross-sectional view illustrating the method of manufacturing the semiconductor device according to the first embodiment;

FIG. 9 is a cross-sectional view illustrating the method of manufacturing the semiconductor device according to the first embodiment;

FIG. 10 is a cross-sectional view illustrating the method of manufacturing the semiconductor device according to the first embodiment;

FIG. 11 is a cross-sectional view illustrating the method of manufacturing the semiconductor device according to the first embodiment;

FIG. 12 is a cross-sectional view illustrating the method of manufacturing the semiconductor device according to the first embodiment;

FIG. 13 is a cross-sectional view illustrating the method of manufacturing the semiconductor device according to the first embodiment;

FIG. 14 is a cross-sectional view illustrating the method of manufacturing the semiconductor device according to the first embodiment;

FIG. 15 is a cross-sectional view illustrating a semiconductor device according to a first variation of the first embodiment;

FIG. 16 is a cross-sectional view illustrating a method of manufacturing the semiconductor device according to the first variation of the first embodiment; and

FIG. 17 is a plan view of a semiconductor device according to a second embodiment.

### DETAILED DESCRIPTION

An organic insulating film may be disposed on the silicon nitride film having the opening exposing the central area of the upper surface of the metal layer so as not to overlap the opening. In this case, the stress of the organic insulating film causes the insulating film to delaminate from the metal layer, starting from the edge of the opening.

There may be a need to provide a semiconductor device which reduces delamination of the insulating film.

According to the present disclosure, delamination of the insulating film is effectively reduced.

### Explanation of Embodiments of the Present Disclosure

The embodiments of the present disclosure will first be listed and described.

(1) An embodiment of the present disclosure is directed to a semiconductor device which includes a substrate, a first metal layer disposed over the substrate, a first inorganic insulating film covering the first metal layer and having a first opening exposing a central area of an upper surface of the first metal layer, a second metal layer disposed on the first metal layer and having a lower surface, a central area of the lower surface being in contact with the first metal layer through the first opening, a peripheral area of the lower surface being in contact with the first inorganic insulating film around the first opening, a second inorganic insulating film covering the second metal layer and having a second opening exposing a central area of an upper surface of the second metal layer, an organic insulating film covering the second inorganic insulating film and having a third opening exposing a central area of the upper surface of the second metal layer and overlapping with the second opening when viewed from a thickness direction of the substrate. With this arrangement, even when the stress of the organic insulating film is applied to the second inorganic insulating film, a part of the first inorganic insulating film sandwiched between the first metal layer and the second metal layer serves as a wedge, which reduces delamination of the second inorganic insulating film from the second metal layer.

(2) In (1), the second metal layer may be thinner than the first metal layer. This arrangement effectively reduces delamination of the second inorganic insulating film from the second metal layer.

(3) In (1) or (2), a width of the lower surface of the second metal layer may be smaller than a width of the upper surface of the first metal layer. This arrangement effectively reduces delamination of the second inorganic insulating film from the second metal layer.

(4) In any of (1) to (3), a perimeter of the second opening may be defined by a perimeter of the third opening. With this arrangement, the manufacturing process is effectively reduced.

(5) In any of (1) to (3), the perimeter of the second opening is located inside the perimeter of the third opening. This arrangement effectively reduces delamination of the second inorganic insulating film from the second metal layer.

(6) In any of (1) to (5), a third metal layer disposed over the substrate, and a third inorganic insulating film covering the third metal layer and having a fourth opening at a central area of an upper surface of the third metal layer may be provided, wherein a central area of a lower surface of the first metal layer may be in contact with the third metal layer through the fourth opening; and a peripheral area of the lower surface of the first metal layer may be in contact with the third inorganic insulating film around the fourth opening. With this arrangement, the intrusion of moisture or the like into the substrate is effectively reduced.

(7) In any of (1) to (6), the organic insulating film may be a polyimide film or a benzocyclobutene film. This arrangement effectively reduces delamination of the second inorganic insulating film from the second metal layer.

(8) In (7), the second inorganic insulating film may be a silicon nitride film, and at least the upper surface of the second metal layer is a gold layer. This effectively reduces delamination of the second inorganic insulating film from the second metal layer.

(9) In any of (1) to (8), the second metal layer may include an adhesion layer forming a lower surface of the second metal layer, and a low resistance layer located on the adhesion layer and having a resistivity lower than that of the adhesion layer. This arrangement effectively improves adhesion between the peripheral area of the lower surface of the second metal layer and the first inorganic insulating film.

(10) In any of (1) to (9), a region of the upper surface of the second metal layer exposed through the second opening and the third opening may be a bonding region. With this arrangement, an external connecting member may be bonded to the bonding region.

### Details of Embodiments of Present Disclosure

Specific examples of the semiconductor device according to the embodiments of the present disclosure will be described below with reference to the drawings. It should be noted that the present disclosure is not limited to these examples, but is defined by the claims and intended to encompass all modifications within the spirit and scope equivalent to what is claimed.

### First Embodiment

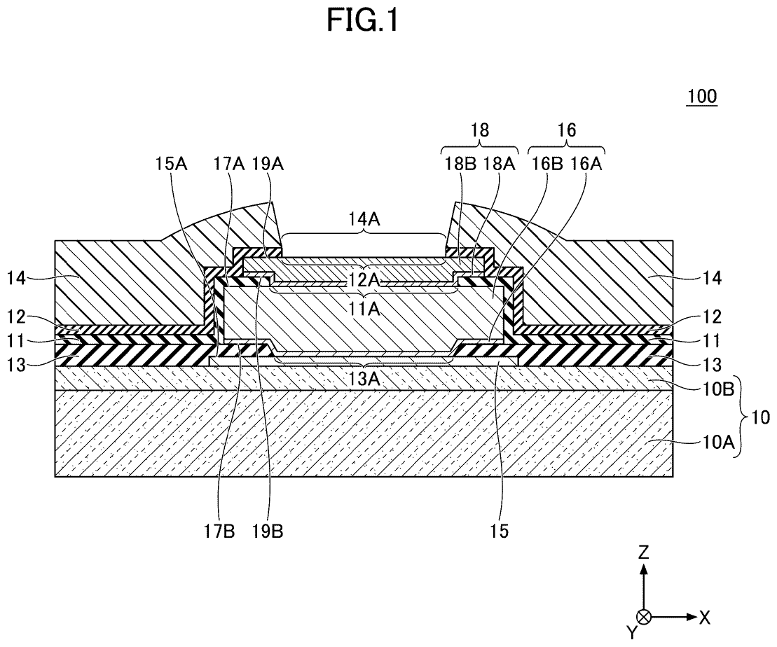

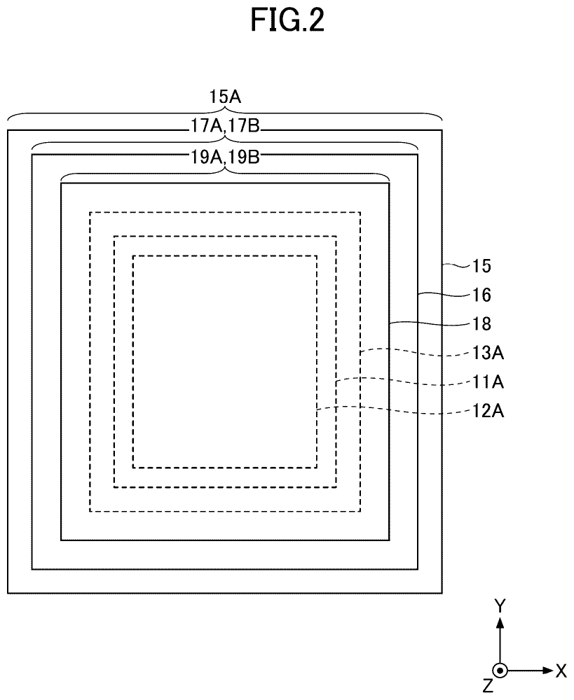

A first embodiment is an example of a semiconductor device including a metal layer that functions as a pad. FIG. 1 is a cross-sectional view of a semiconductor device according to the first embodiment. FIG. 2 is a plan view illustrating metal layers 15, 16, and 18 and openings 13A, 11A, and 12A of the semiconductor device according to the first embodiment. In FIG. 2, an upper surface 15A of the metal layer 15, an upper surface 17A and a lower surface 17B of the metal layer 16, and an upper surface 19A and a lower surface 19B of the metal layer 18 are illustrated. Although the sizes of the upper surface 17A and the lower surface 17B are not necessarily the same, and the sizes of the upper surface 19A and the lower surface 19B are not necessarily the same, FIG. 2 shows the upper surface 17A and the lower surface 17B as being the same size, and the upper surfaces 19A and the lower surface 19B as being the same size. The thickness direction of the substrate 10 is the Z direction, and directions orthogonal to the Z direction and orthogonal to each other are the X direction and the Y direction.

As illustrated in FIGS. 1 and 2, a semiconductor device 100 according to the first embodiment includes a substrate 10, metal layers 15, 16, and 18, inorganic insulating films 11, 12, and 13, and an organic insulating film 14. The substrate 10 includes a substrate 10A and a semiconductor layer 10B disposed on the substrate 10A. The metal layer 15 is located on the substrate 10. The inorganic insulating film 13 is provided on the substrate 10 so as to cover the metal layer 15. The inorganic insulating film 13 has an opening 13A which exposes a central area of the upper surface 15A of the metal layer 15 and does not expose the peripheral area of the upper surface 15A of the metal layer 15.

The metal layer 16 is disposed on the metal layer 15 and the inorganic insulating film 13. A central area of the lower surface 17B of the metal layer 16 is in contact with the metal layer 15 through the opening 13A. The peripheral area of the lower surface 17B of the metal layer 16 is in contact with the inorganic insulating film 13 around the opening 13A. The metal layer 16 includes a metal layer 16A in contact with the upper surfaces of the metal layer 15 and the inorganic insulating film 13, and a metal layer 16B located on the metal layer 16A. The metal layer 16A is an adhesion layer for improving adhesion between the metal layer 16B and each of the metal layer 15 and the inorganic insulating film 13. The metal layer 16B is a low resistance layer having a resistivity lower than that of the metal layer 16A. The inorganic insulating film 11 is provided over the substrate 10 so as to cover the metal layer 16 and the inorganic insulating film 13. The inorganic insulating film 11 has an opening 11A which exposes a central area of the upper surface 17A of the metal layer 16 and does not expose the peripheral area of the upper surface 17A of the metal layer 16.

The metal layer 18 is disposed on the metal layer 16 and the inorganic insulating film 11. A central area of the lower surface 19B of the metal layer 18 is in contact with the metal layer 16 through the opening 11A. The peripheral area of the lower surface 19B of the metal layer 18 is in contact with the inorganic insulating film 11 around the opening 11A. The metal layer 18 includes a metal layer 18A in contact with the upper surfaces of the metal layer 16 and the inorganic insulating film 11, and a metal layer 18B located on the metal layer 18A. The metal layer 18A is an adhesion layer for improving adhesion between the metal layer 18B and each of the metal layer 16 and the inorganic insulating film 11. The metal layer 18B is a low resistance layer having a resistivity lower than that of the metal layer 18A. The inorganic insulating film 12 is provided over the substrate 10 so as to cover the metal layer 18 and the inorganic insulating film 11. The inorganic insulating film 12 has an opening 12A which exposes a central area of the upper surface 19A of the metal layer 18 and does not expose the peripheral area of the upper surface 19A of the metal layer 18.

The organic insulating film 14 has an opening 14A which exposes the central area of the upper surface of the metal layer 18 and does not expose the peripheral area of the upper surface of the metal layer 18. The perimeter of the opening 12A is defined by the perimeter of the opening 14A. The perimeters of the openings 12A and 14A are substantially aligned. The perimeters of the openings 12A and 14A may not necessarily coincide. On the upper surface of the metal layer 18 exposed through the openings 12A and 14A, a member for connecting to the outside such as a bonding wire or a bump is bonded. In this manner, the upper surface of the metal layer 18 exposed through the openings 12A and 14A functions as a pad.

The semiconductor layer 10B is a nitride semiconductor layer, an arsenide semiconductor layer, or a silicon layer. The nitride semiconductor layer is, for example, gallium nitride, aluminum nitride, indium nitride, or a mixed crystal thereof. The arsenide semiconductor layer is, for example, gallium arsenide, aluminum arsenide, indium arsenide, or a mixed crystal thereof. When the semiconductor layer 10B is a nitride semiconductor layer, the substrate 10A is, for example, a silicon carbide substrate, sapphire substrate, or gallium nitride substrate. When the semiconductor layer 10B is an arsenide semiconductor layer, the substrate 10A is, for example, a gallium arsenide substrate. When the semiconductor layer 10B is a silicon layer, the substrate 10A is, for example, a silicon substrate.

The inorganic insulating films 11 to 13 are, for example, a silicon nitride film, a silicon oxide film, a silicon nitride oxide film, or an aluminum oxide film, and are, for example, each a silicon nitride film. The main components of the inorganic insulating films 11 to 13 may be the same or different from each other. The organic insulating film 14 may be, for example, a polyimide film or a benzocyclobutene (BCB) film, and is a polyimide film in this example. The metal layers 16A and 18A may be, for example, a titanium layer, a titanium tungsten layer, a titanium nitride layer, or a titanium tungsten nitride layer. The main components of the metal layers 16A and 18A may be the same or different from each other. The metal layers 16B and 18B may be, for example, a gold layer, a copper layer, or an aluminum layer. The main components of the metal layers 16B and 18B may be the same or different from each other. The resistivities of the metal layers 16B and 18B may be, for example, at most ½, and preferably at most ⅕, of the resistivities of the metal layers 16A and 18A, respectively.

### Comparative Example

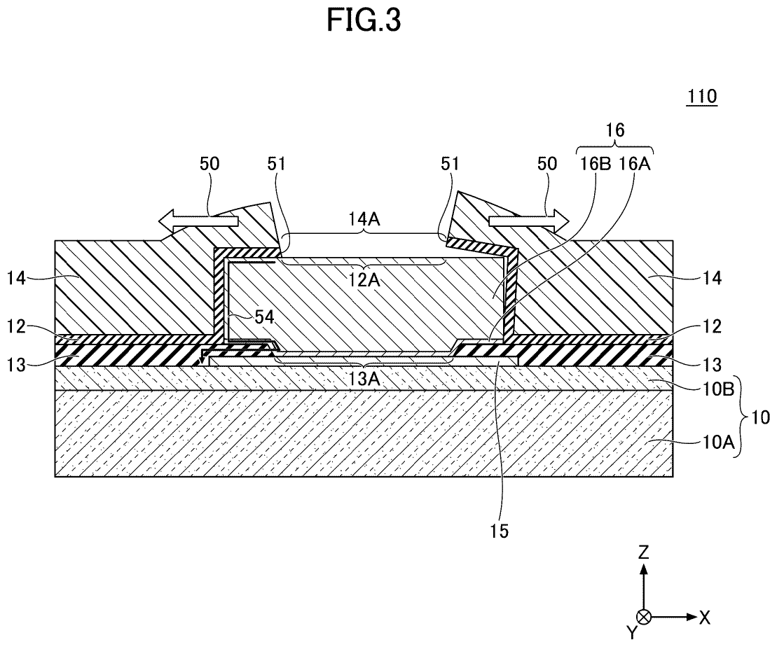

FIG. 3 is a cross-sectional view of a semiconductor device according to a comparative example. As illustrated in FIG. 3, a semiconductor device 110 according to the comparative example is such that the inorganic insulating film 11 and the metal layer 18 are not provided. The inorganic insulating film 12 is provided so as to cover the metal layer 16. The inorganic insulating film 12 has an opening 12A which exposes a central area of the upper surface of the metal layer 16 and does not expose the peripheral area of the upper surface of the metal layer 16. Other configurations are the same as those of the first embodiment.

The inorganic insulating film 12 and the organic insulating film 14 are used as protective films, and the organic insulating film 14 generally has a larger linear expansion coefficient than inorganic insulating films and metal layers. Therefore, after the heat treatment of the organic insulating film 14, the organic insulating film 14 incurs stress 50 due to its contraction. The stress is concentrated at the edge of the opening 14A of the organic insulating film 14 and the edge 51 of the opening 12A of the inorganic insulating film 12. In general, adhesion between an inorganic insulating film and a metal layer is weak. The inorganic insulating film 12 may thus delaminate from the metal layer 16, starting from the edge 51 of the opening 12A of the inorganic insulating film 12. Also, moisture or the like readily intrudes into a path 54 extending from the edge 51 of the inorganic insulating film 12 to the substrate 10 along the interfaces between the metal layers 15 and 16 and the inorganic insulating films 12 and 13, thereby reading the substrate 10. The moisture or the like that has reached the substrate 10 may reach a transistor, crossing the interface between the substrate 10 and the inorganic insulating film 13.

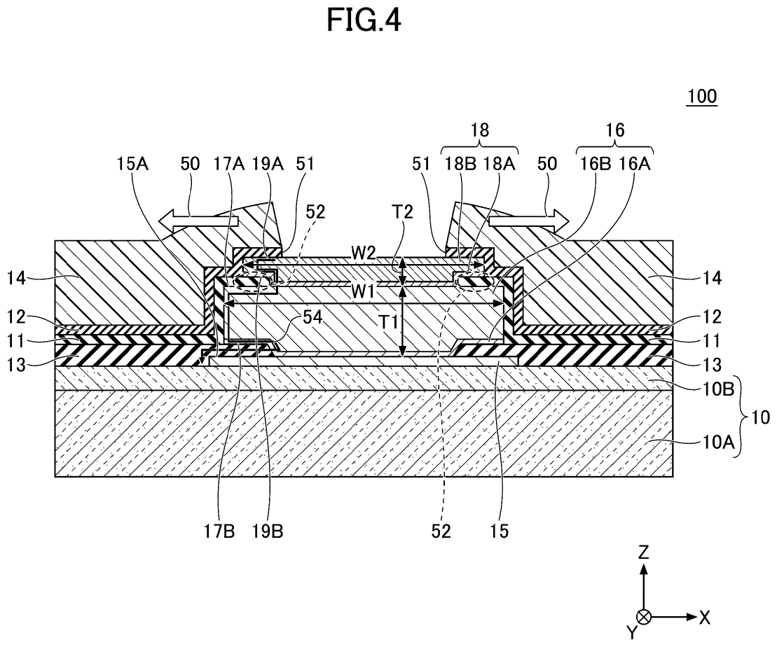

FIG. 4 is a cross-sectional view of the semiconductor device according to the first embodiment. As illustrated in FIGS. 1, 2 and 4, according to the semiconductor device 100 of the first embodiment, the metal layer 16 (first metal layer) is disposed over the substrate 10. The inorganic insulating film 11 (first inorganic insulating film) covers the metal layer 16, and has the opening 11A (first opening) that exposes the central area of the upper surface 17A of the metal layer 16. The metal layer 18 (second metal layer) is disposed on the metal layer 16, with the central area of the lower surface 19B in contact with the metal layer 16 through the opening 11A, and the peripheral area of the lower surface 19B in contact with the inorganic insulating film 11 around the opening 11A. The inorganic insulating film 12 (second inorganic insulating film) covers the metal layer 18, and has the opening 12A (second opening) that exposes the central area of the upper surface 19A of the metal layer 18. The organic insulating film 14 covers the inorganic insulating film 12, and has the opening 14A (third opening) exposing the central area of the upper surface 19A of the metal layer 18. When viewed from the Z direction, the opening 14A is aligned with the opening 12A.

In the manner as described above, a part of the inorganic insulating film 11 is sandwiched between the metal layers 16 and 18. With this arrangement, even when the stress 50 of the organic insulating film 14 is applied to the inorganic insulating film 11, the part of the inorganic insulating film 11 sandwiched between the metal layers 16 and 18 serves as a wedge 52, thereby reducing delamination of the inorganic insulating film 12 from the metal layer 18. Moreover, the length of the path 54 from the edge 51 of the inorganic insulating film 12 to the substrate 10 along the interfaces between the metal layers 15, 16 and 18 and the inorganic insulating films 11, 12 and 13 is greater than that of the comparative example. As a result, the intrusion of moisture or the like into the substrate 10 via the path 54 extending along the interfaces is reduced, which makes it unlikely for moisture to reach a transistor or the like. Since the number of bends of the path 54 is greater than that of the comparative example, the intrusion of moisture or the like into the substrate 10 via the path 54 is further reduced.

The metal layer 18 is thinner than the metal layer 16. This arrangement reduces the distance along the inorganic insulating film 12 from the wedge 52 to the edge 51 of the inorganic insulating film 12. As a result, even when stress is applied to the edge 51 of the inorganic insulating film 12, the inorganic insulating film 12 is unlikely to delaminate from the metal layer 18. The thickness T2 of the metal layer 18 may be at most 0.9 times the thickness T1 of the metal layer 16, and preferably at most 0.8 times. The thickness T2 of the metal layer 18 may alternatively be greater than the thickness T1 of the metal layer 16.

The width W2 of the lower surface 19B of the metal layer 18 is less than the width W1 of the upper surface 17A of the metal layer 16. This arrangement reduces the distance along the inorganic insulating film 12 from the wedge 52 to the edge 51 of the inorganic insulating film 12. As a result, even when stress is applied to the edge 51 of the inorganic insulating film 12, the inorganic insulating film 12 is unlikely to delaminate from the metal layer 18. The width W2 of the metal layer 18 may be at most 0.95 times the width W1 of the metal layer 16, and preferably at most 0.9 times.

The metal layer 15 (third metal layer) is disposed on the substrate 10. The inorganic insulating film 13 (third inorganic insulating film) covers the metal layer 15 and has the opening 13A (fourth opening) at the central area of the upper surface 15A of the metal layer 15. The central area of the lower surface 17B of the metal layer 16 is in contact with the metal layer 15 through the opening 13A, and the peripheral area of the lower surface 17B is in contact with the inorganic insulating film 13 around the opening 13A. This arrangement reduces the intrusion of moisture or the like into the substrate 10 via the path 54, making it unlikely for moisture to reach a transistor or the like.

When the organic insulating film 14 is a polyimide film or a BCB film, the organic insulating film 14 incurs the stress 50. Provision of the wedge 52 in this case effectively reduces delamination of the inorganic insulating film 12 from the metal layer 18.

When the inorganic insulating film 12 is a silicon nitride film and at least the upper surface of the metal layer 18 is a gold layer, adhesion between the inorganic insulating film 12 and the metal layer 18 is weak. The provision of the wedge 52 effectively reduces delamination of the inorganic insulating film 12 from the metal layer 18.

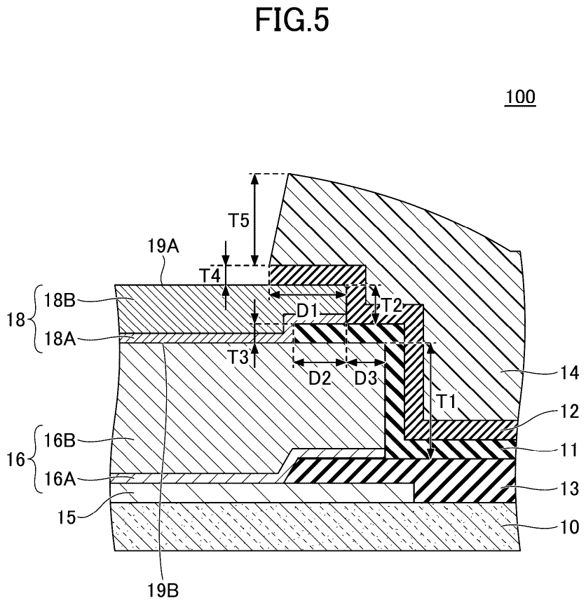

FIG. 5 is an enlarged cross-sectional view of a portion of the semiconductor device according to the first embodiment. In FIG. 5, the distance covered by the inorganic insulating film 12 on the upper surface 19A of the metal layer 18, that is, the distance between the side surface of the metal layer 18 and the end surface of the inorganic insulating film 12, is D1. When the distance D1 is short, moisture or the like easily intrude into an interface between the metal layer 18 and the inorganic insulating film 12, resulting in the deterioration of moisture resistance. For moisture resistance, the distance D1 is, for example, 1 μm or more. For size reduction, the distance D1 is, for example, 10 μm or less. The distance D1 may be, for example, at least 0.2 times and at most 10 times the thickness T2 of the metal layer 18, and preferably at least 1 time and at most 5 times.

The distance covered by the inorganic insulating film 11 on the lower surface 19B of the metal layer 18, that is, the distance between the side surface of the metal layer 18 and the end surface of the inorganic insulating film 11, is D2. For overlay accuracy between the metal layer 18 and the inorganic insulating film 12, the distance D2 is, for example, 0.5 μm or more. For a large contact area between the metal layers 16 and 18, the distance D2 is, for example, at most 10 μm. The distance D2 may be, for example, at least 0.1 times and at most 20 times the thickness T2 of the metal layer 18, and preferably at least 0.5 times and at most 10 times.

The distance between the side surface of the metal layer 16 and the side surface of the metal layer 18 is D3. For overlay accuracy between the metal layers 16 and 18, the distance D3 is, for example, 0.5 μm or more. For size reduction, the distance D3 is, for example, 5 μm or less. The distance D3 may be, for example, at least 0.1 times and at most 10 times the thickness T2 of the metal layer 18, and preferably at least 0.5 times and at most 5 times.

The thickness T1 of the metal layer 16 is, for example, 1 μm or more in order to reduce the current density, and 5 μm or less in order to reduce the manufacturing process. The thickness T2 of the metal layer 18 is, for example, 1 μm or more in order to reduce the current density, and 5 μm or less in order to reduce the manufacturing process.

The thickness T3 of the inorganic insulating film 11 is, for example, 0.1 μm or more for the purpose of reducing pinholes and the like, and is, for example, 0.4 μm or less for the purpose of reducing parasitic capacitance. The thickness T4 of the inorganic insulating film 12 is, for example, 0.2 μm or more in order to reduce pinholes and the like, and is, for example, 0.8 μm or less in order to reduce parasitic capacitance.

The thickness T5 of the organic insulating film 14 near the opening 14A is, for example, 1 μm or more for its function as a protective film, and is, for example, 10 μm or less for reducing manufacturing steps. Use of the organic insulating film 14 as a protective film requires a greater thickness T5. However, an increase in the thickness T5 causes an increase in the stress applied to the edge 51. When the organic insulating film 14 becomes thick, providing the metal layers 16 and 18 effectively reduces delamination of the inorganic insulating film 12.

### Manufacturing Method of First Embodiment

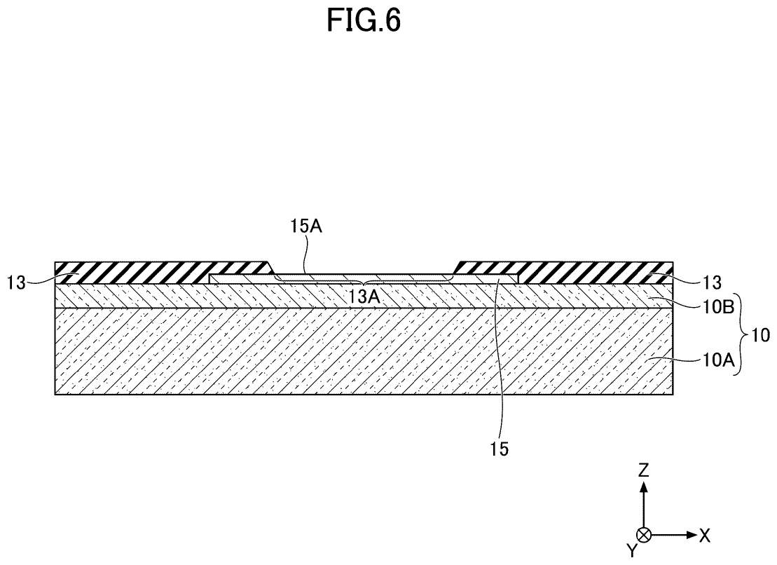

FIGS. 6 to 14 are cross-sectional views illustrating a method of manufacturing a semiconductor device according to the first embodiment. As illustrated in FIG. 6, a metal layer 15 is formed on a substrate 10. The metal layer 15 is formed by, for example, a vacuum evaporation method and a lift-off method. An inorganic insulating film 13 is formed on the substrate 10 so as to cover the metal layer 15. An opening 13A is formed on the inorganic insulating film 13 so as to expose the central area of the upper surface 15A of the metal layer 15 and not expose the peripheral area of the upper surface 15A. The inorganic insulating film 13 is formed by, for example, a chemical vapor deposition (CVD) method. The opening 13A is formed by, for example, a photolithography method and a dry etching method.

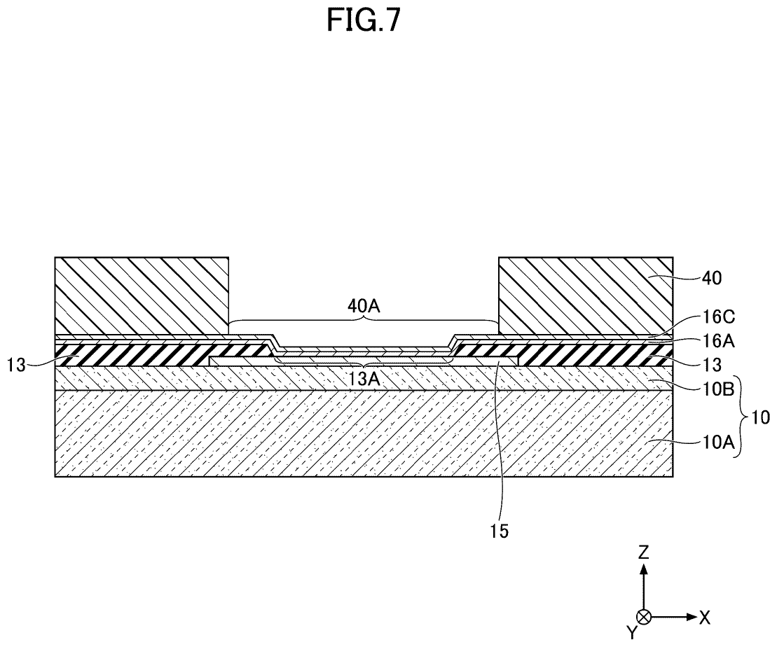

As illustrated in FIG. 7, metal layers 16A and 16C are formed in the opening 13A and on the inorganic insulating film 13. The metal layer 16A is an adhesion layer. The metal layer 16C is a seed layer for forming the metal layer 16B, and the main component of the metal layer 16C is the same as, for example, the main component of the metal layer 16B. The metal layers 16A and 16C are formed by, for example, sputtering. A mask layer 40 is formed on the metal layer 16A. The mask layer 40 has an opening 40A which overlaps with the opening 13A and is larger than the opening 13A when viewed from the Z direction. The mask layer 40 is, for example, a photoresist and is formed by a photolithography method.

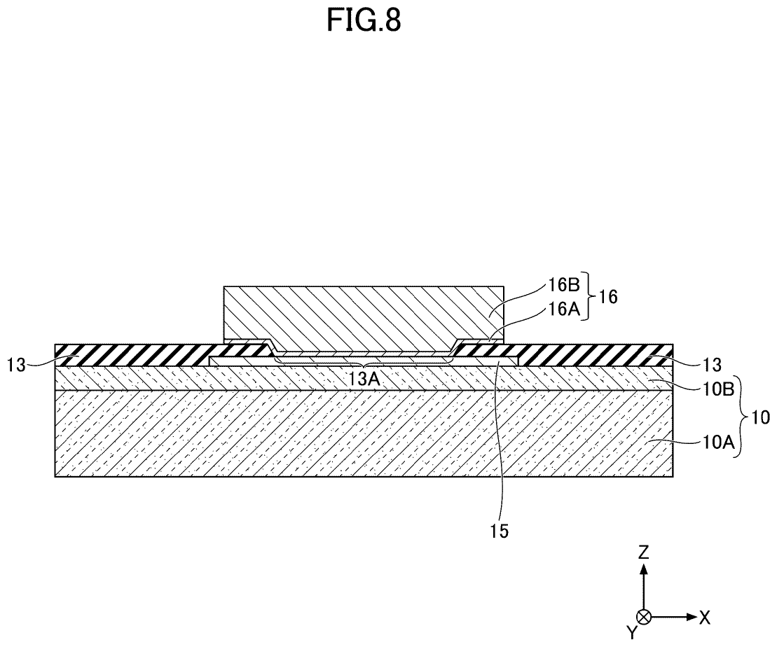

As illustrated in FIG. 8, the metal layer 16B is formed in the opening 40A of the mask layer 40. The metal layer 16B is formed by an electrolytic plating method by supplying current, for example, through the metal layers 16A and 16C. In the following figures, the illustration of the metal layer 16C is omitted. A metal layer 16 is formed as a stack of the metal layers 16A and 16B. The mask layer 40 is removed. The metal layer 16A is etched using the metal layer 16B as a mask. This removes the metal layer 16A outside the region where the metal layer 16B is formed.

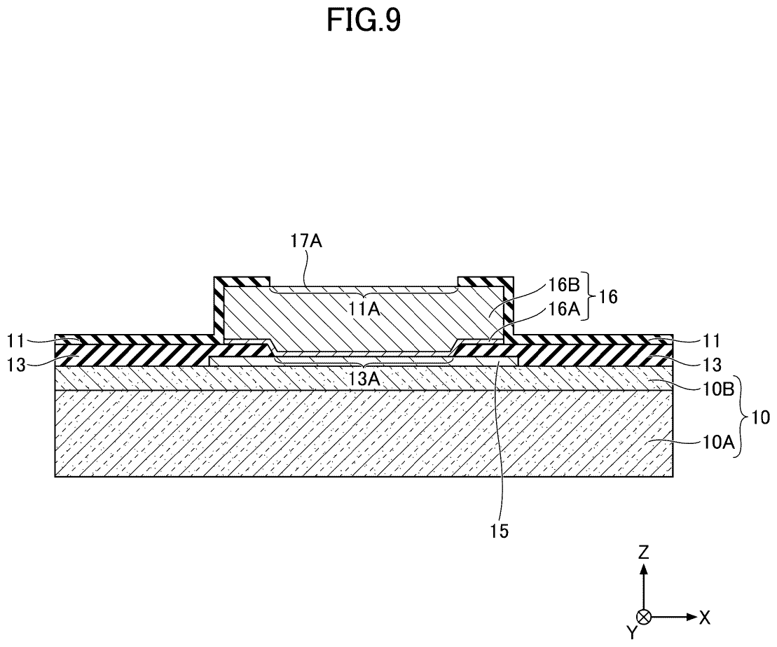

As illustrated in FIG. 9, an inorganic insulating film 11 is formed on the inorganic insulating film 13 so as to cover the metal layer 16. The inorganic insulating film 11 is formed by, for example, a CVD method. An opening 11A is formed in the inorganic insulating film 11 so that the central area of the upper surface 17A of the metal layer 16 is exposed and the peripheral area of the upper surface 17A is not exposed. The opening 11A is formed by, for example, photolithography and dry etching.

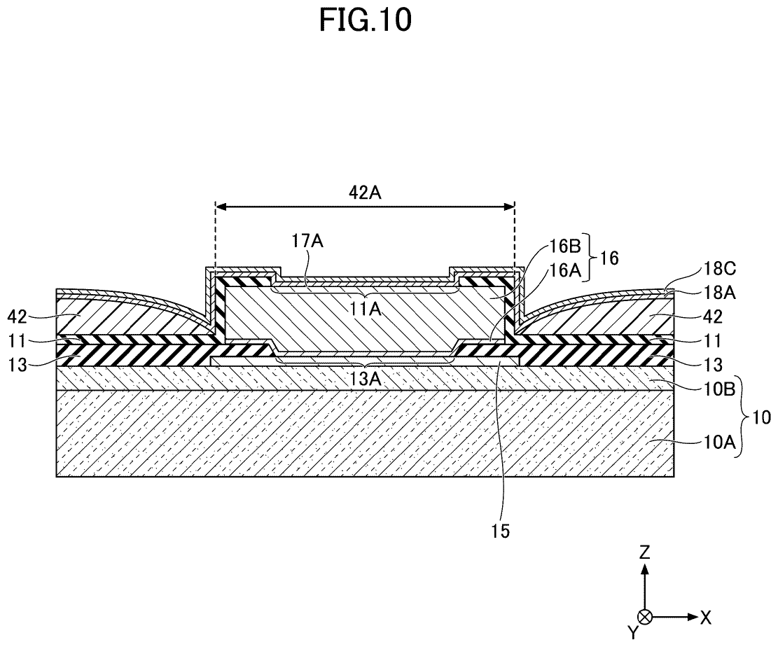

As illustrated in FIG. 10, a mask layer 42 is formed on the inorganic insulating film 11. The mask layer 42 has an opening 42A. The opening 42A exposes the metal layer 16 and the inorganic insulating film 11 formed on the side surface of the metal layer 16. The upper surface of the mask layer 42 near the opening 42A has a curved surface such that the thickness of the mask layer 42 gradually decreases toward the opening 42A. The mask layer 42 is, for example, a photoresist, and is formed by photolithography. After the opening 42A is formed in the mask layer 42, heat treatment is performed, which makes the upper surface of the mask layer 42 a curved surface. Metal layers 18A and 18C are formed on the mask layer 42, on the metal layer 16 in the opening 42A, and on the inorganic insulating film 11 in the opening 42A. The metal layer 18A is an adhesion layer. The metal layer 18C is a seed layer for forming the metal layer 18B, and the main component of the metal layer 18C is, for example, the same as the main component of the metal layer 18B. The metal layers 18A and 18C are formed by, for example, sputtering.

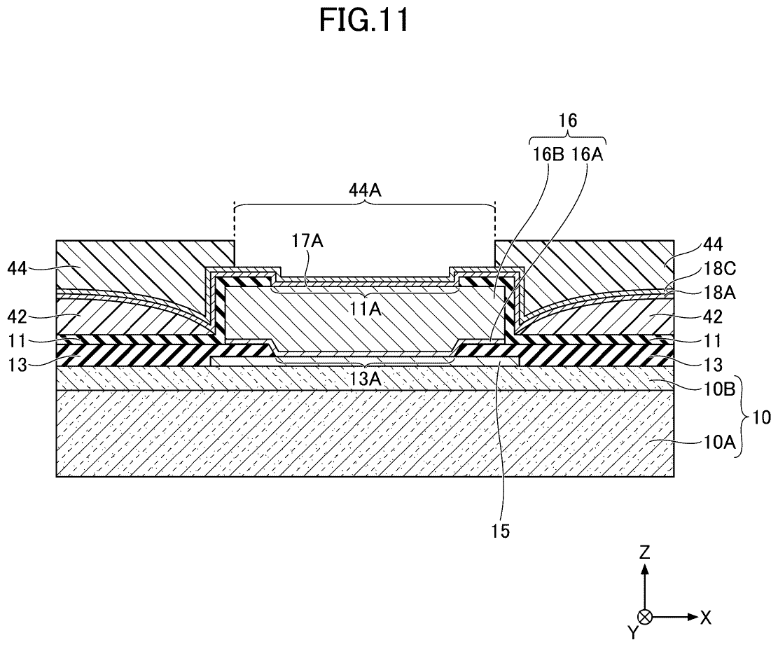

As illustrated in FIG. 11, a mask layer 44 is formed on the metal layer 18A. The mask layer 44 has an opening 44A. The opening 44A is larger than the opening 11A and smaller than the upper surface 17A of the metal layer 16. The mask layer 44 is, for example, a photoresist and is formed by a photolithography method.

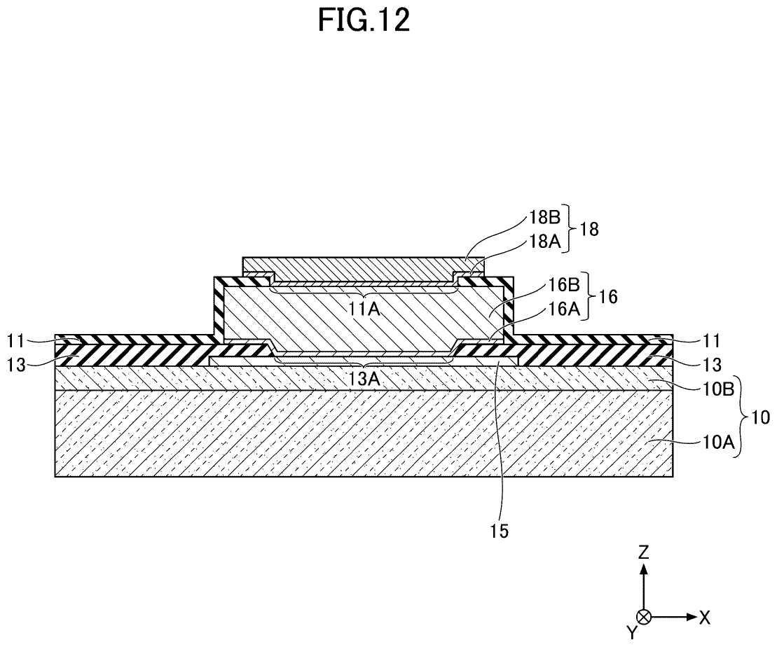

As illustrated in FIG. 12, a metal layer 18B is formed in the opening 44A of the mask layer 44. The metal layer 18B is formed by an electrolytic plating method, for example, by supplying current through the metal layer 18A. In the following figures, the illustration of the metal layer 18C is omitted. The metal layer 18 is formed as a stack of the metal layers 18A and 18B. The mask layer 44 is removed. The metal layer 18A is etched using the metal layer 18B as a mask. This removes the metal layer 18A outside the region where the metal layer 18B is formed. The mask layer 42 is then removed.

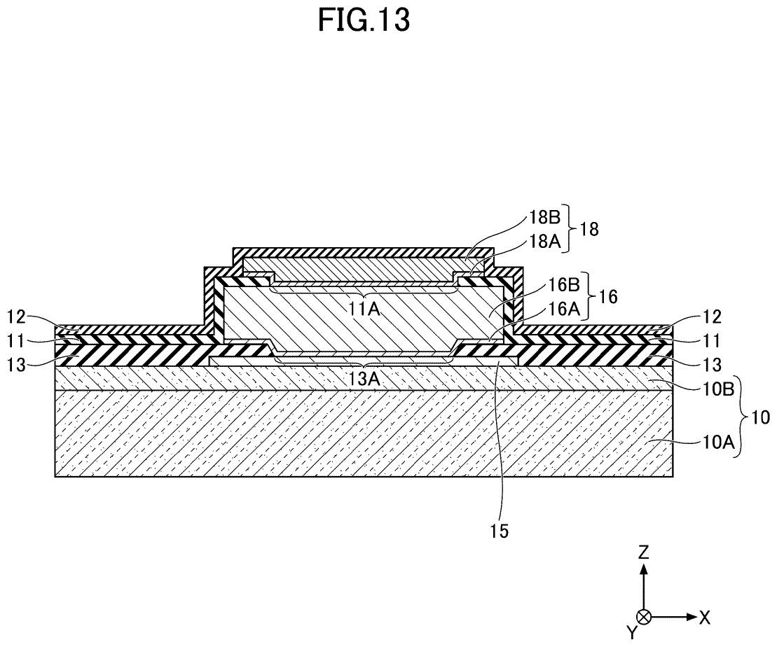

As illustrated in FIG. 13, an inorganic insulating film 12 is formed on the inorganic insulating film 11 so as to cover the metal layer 18. The inorganic insulating film 12 is formed by, for example, a CVD method.

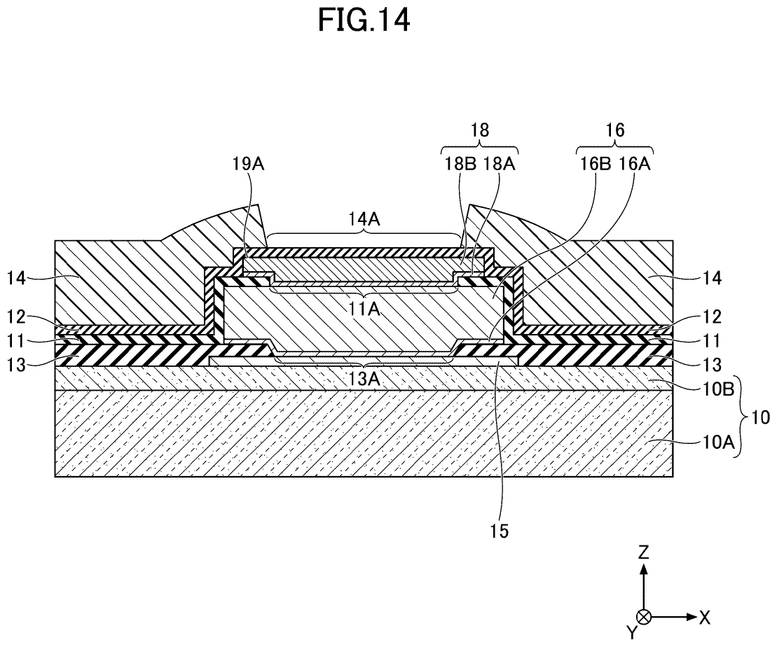

As illustrated in FIG. 14, an organic insulating film 14 is formed on the inorganic insulating film 12. The organic insulating film 14 has an opening 14A. The opening 14A is smaller than the upper surface 19A of the metal layer 18. The organic insulating film 14 is, for example, a photosensitive polyimide film, and is formed by photolithography.

Subsequently, the inorganic insulating film 12 is removed using the organic insulating film 14 as a mask. This arrangement forms an opening 12A in the inorganic insulating film 12. Following these steps results in the semiconductor device 100 according to the first embodiment illustrated in FIG. 1.

In the first embodiment, using the organic insulating film 14 as a mask to remove the inorganic insulating film 12 eliminates the need for the mask layer for forming the opening 12A of the inorganic insulating film 12, thereby reducing the manufacturing process. Since the organic insulating film 14 is used as a mask to remove the inorganic insulating film 12, the perimeter of the opening 12A is defined by the perimeter of the opening 14A.

Further, the metal layer 18 is formed in the manner illustrated in FIGS. 10 to 12. In this case, the metal layer 18 includes the metal layer 18A (adhesion layer) forming the lower surface 19B of the metal layer 18, and the metal layer 18B (low resistance layer) located on the metal layer 18A and having a resistivity lower than that of the metal layer 18A. This arrangement improves adhesion between a peripheral area of the lower surface 19B of the metal layer 18 and the inorganic insulating film 11. As a result, effective formation of the metal layer 18 on the inorganic insulating film 11 is achieved.

### First Variation of First Embodiment

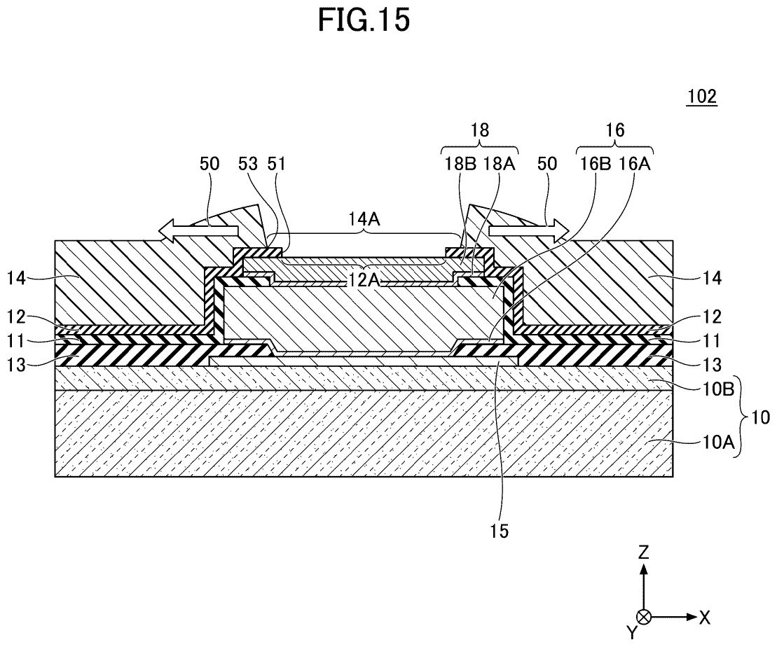

FIG. 15 is a cross-sectional view of a semiconductor device according to a first variation of the first embodiment. As illustrated in FIG. 15, a semiconductor device 102 according to the first variation of the first embodiment is such that the opening 14A of the organic insulating film 14 is larger than the opening 12A of the inorganic insulating film 12. The edge 51 of the inorganic insulating film 12 is positioned inside an edge 53 of the organic insulating film 14. That is, the perimeter of the opening 12A is positioned inside the perimeter of the opening 14A.

In the first variation of the first embodiment, the stress 50, when generated in the organic insulating film 14, is mainly applied to the edge 53 of the organic insulating film 14, and is only slightly applied to the edge 51 of the inorganic insulating film 12. With this arrangement, delamination of the inorganic insulating film 12 from the metal layer 16 is effectively reduced.

### Manufacturing Method of First Variation of the First Embodiment

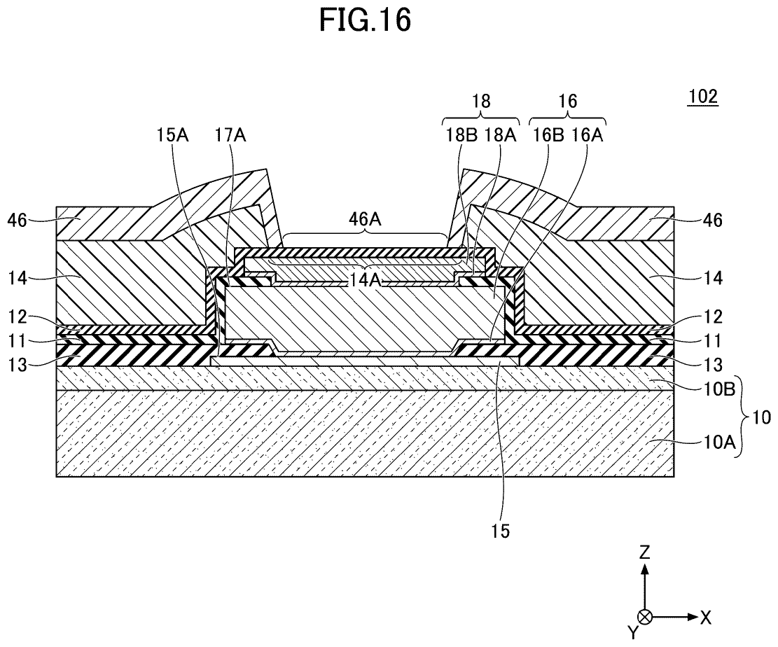

FIG. 16 is a cross-sectional view illustrating a manufacturing method of the semiconductor device according to the first variation of the first embodiment. As illustrated in FIG. 16, after FIG. 14 of the first embodiment, a mask layer 46 is formed on the organic insulating film 14. The mask layer 46 has an opening 46A smaller than the opening 14A. The mask layer 46 is, for example, a photoresist, and is formed by photolithography.

After FIG. 16, the inorganic insulating film 12 is removed using the mask layer 46 as a mask. For example, dry etching is used to remove the inorganic insulating film 12. The mask layer 46 is then removed. This process results in the semiconductor device 102.

### Second Embodiment

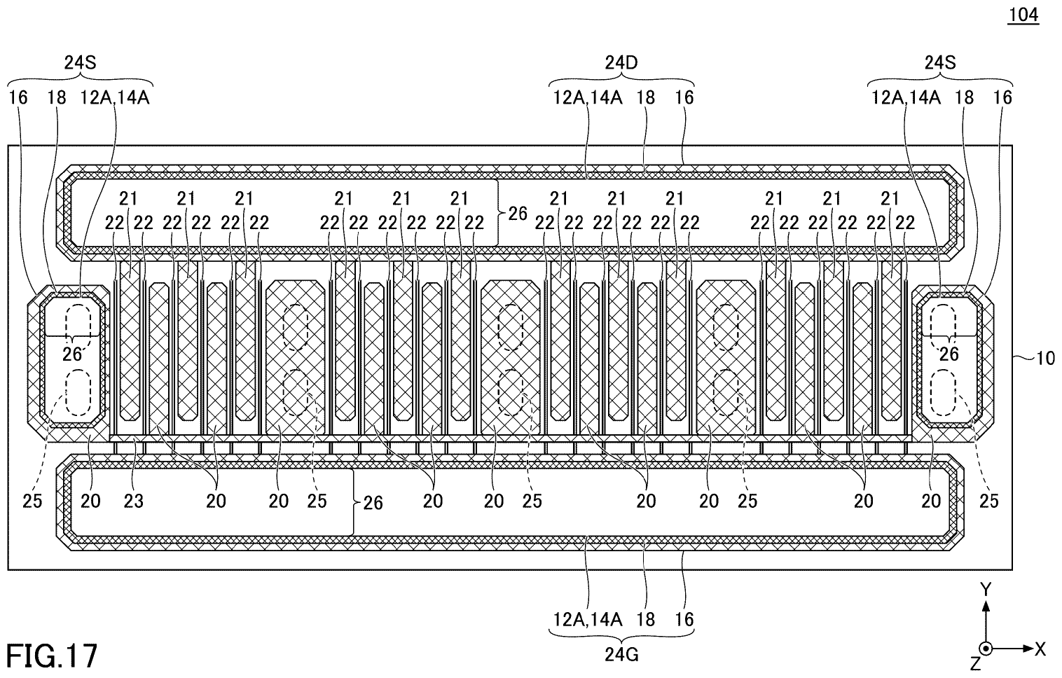

In the second embodiment, the structure of the metal layers 16 and 18 of the first embodiment and its first variation is used as a pad of a transistor. FIG. 17 is a plan view of a semiconductor device according to the second embodiment.

As illustrated in FIG. 17, a semiconductor device 104 according to the second embodiment includes a substrate 10, source electrodes 20, drain electrodes 21, gate electrodes 22, and pads 24S, 24D, and 24G. The source electrodes 20 and the drain electrodes 21 are disposed alternately along the X direction. The gate electrodes 22 are located between the source electrodes 20 and the drain electrodes 21 in the X direction. The source electrodes 20, the drain electrodes 21, and the gate electrodes 22 are finger-shaped and extend in the Y direction.

The source electrodes 20 are arranged, with every third one being wider in the X direction. Via holes 25 penetrating the substrate 10 are connected to the thick source electrodes 20. The thick source electrodes 20 are electrically connected to a metal layer disposed on the lower surface of the substrate 10 through the via holes 25. The thin source electrodes 20 are electrically connected to the thick source electrode 20 via a source interconnect 23. The source interconnect 23 crosses the gate electrodes 22 in a non-contacting manner. The outermost source electrodes 20 in the X direction are electrically connected to the pads 24S.

The drain electrodes 21 are electrically connected to the pad 24D. The gate electrodes 22 are electrically connected to the pad 24G. Each of the pads 24S, 24D, and 24G has the metal layers 16 and 18 and the openings 12A and 14A. The structures of the pads 24S, 24D, and 24G are the same as those of the first embodiment or the first variation thereof, and will not be described. The area of the upper surface of the metal layer 18 exposed through the openings 12A and 14A is a bonding region 26. External connecting members such as bonding wires or bumps may be bonded to the bonding regions 26. Also, probes for electrical testing may be brought in contact with the bonding regions 26. Since a voltage is supplied to the source electrodes 20 from the metal layer on the lower surface of the substrate 10 through the via holes 25, the external connecting members need not be bonded to the pads 24S. The pads 24S may be used for contact with the probes for electrical testing.

The source electrodes 20 and the drain electrodes 21 are implemented as a stack of the metal layers 15 and 16 laminated in this order starting from the substrate 10 side. When the semiconductor device 104 is a GaN HEMT, the metal layer 15 is, for example, a titanium layer and an aluminum layer in this order starting from the substrate 10 side. The gate electrodes 22 are, for example, a nickel layer and a gold layer in this order starting from the substrate 10 side.

The second embodiment is directed to an example in which an FET is used as an example of a transistor, but the transistor may not be an FET, and may be a bipolar transistor.

The embodiments disclosed herein are to be considered as illustrative and non-restrictive in all respects. The scope of the present disclosure is defined by the claims, not by what is expressed in the above descriptions, and is intended to include all modifications within the scope and spirit equivalent to the scope of the claims.

What is claimed is:

1. A semiconductor device comprising:
a substrate;
a first metal layer disposed over the substrate;
a first inorganic insulating film covering the first metal layer and having a first opening exposing a central area of an upper surface of the first metal layer;
a second metal layer disposed on the first metal layer and having a lower surface, a central area of the lower surface being in contact with the first metal layer through the first opening, a peripheral area of the lower surface being in contact with the first inorganic insulating film around the first opening;
a second inorganic insulating film covering the second metal layer and having a second opening exposing a central area of an upper surface of the second metal layer; and
an organic insulating film covering the second inorganic insulating film and having a third opening exposing a central area of the upper surface of the second metal layer and overlapping with the second opening when viewed from a thickness direction of the substrate.

2. The semiconductor device according to claim 1, wherein the second metal layer is thinner than the first metal layer.

3. The semiconductor device according to claim 1, wherein a width of the lower surface of the second metal layer is smaller than a width of the upper surface of the first metal layer.

4. The semiconductor device according to claim 1, wherein a perimeter of the second opening is defined by a perimeter of the third opening.

5. The semiconductor device according to claim 1, wherein a perimeter of the second opening is located inside a perimeter of the third opening.

6. The semiconductor device according to claim 1, comprising:
a third metal layer disposed over the substrate; and
a third inorganic insulating film covering the third metal layer and having a fourth opening at a central area of an upper surface of the third metal layer,
wherein a central area of a lower surface of the first metal layer is in contact with the third metal layer through the fourth opening; and a peripheral area of the lower surface of the first metal layer is in contact with the third inorganic insulating film around the fourth opening.

7. The semiconductor device according to claim 1, wherein the organic insulating film is a polyimide film or a benzocyclobutene film.

8. The semiconductor device according to claim 7, wherein the second inorganic insulating film is a silicon nitride film, and at least the upper surface of the second metal layer is a gold layer.

9. The semiconductor device according to claim 1, wherein the second metal layer includes an adhesion layer forming a lower surface of the second metal layer, and a low resistance layer located on the adhesion layer and having a resistivity lower than that of the adhesion layer.

10. The semiconductor device according to claim 1, wherein a region of the upper surface of the second metal layer exposed through the second opening and the third opening is a bonding region.
